(19) United States
(12) Patent Application Publication
(10) Pub. No.: US 2002/0146636 A1
(43) Pub. Date: Oct. 10, 2002

(54) Reverse transfer imaging and methods of printing

(76) Inventor: Ernest W. Ellis, Harvard, MA (US)

Correspondence Address: TESTA, HURWITZ & THIBEAULT, LLP, HIGH STREET TOWER, 125 HIGH STREET, BOSTON, MA, 02110, US

(21) Appl. No.: 09/827,799

(22) Filed: Apr. 6, 2001

(51) Int. Cl. G03F 7/34; G03F 7/09; G03F 7/11

(52) U.S. Cl. 430/200; 430/201; 430/253; 430/271.1; 430/272.1; 430/276.1; 430/278.1; 430/279.1; 430/302

(57) ABSTRACT

Lithographic imaging techniques begin with a donor member having substrate substantially transparent to imaging radiation and a transferable material thereover; the substrate and the transferable material differ in affinity for ink and/or a liquid to which ink will not adhere. The donor member is exposed to imaging radiation in an imagewise pattern so as to cause displacement of the transfer material from the donor member in accordance with that pattern. Following the imagewise displacement, the donor member can be used as a lithographic printing member.

### FIELD OF THE INVENTION

The present invention relates to imaging with laser devices, and in particular to transfer-type imaging of lithographic printing plates.

### BACKGROUND OF THE INVENTION

In offset lithography, an image to be transferred to a recording medium is represented on a plate, mat or other printing member as a pattern of ink-accepting (oleophilic) and ink-repellent (oleophobic) surface areas. In a dry printing system, the member is simply inked and the image transferred onto a recording material; the member first makes contact with a compliant intermediate surface called a blanket cylinder which, in turn, applies the image to the paper or other recording medium. In typical sheet-fed press systems, the recording medium is pinned to an impression cylinder, which brings it into contact with the blanket cylinder.

In a wet lithographic system, the non-image areas are hydrophilic in the sense of affinity for dampening (or “fountain”) solution, and the necessary ink-repellency is provided by an initial application of such a solution to the plate prior to inking. The fountain solution prevents ink from adhering to the non-image areas, but does not affect the oleophilic character of the image areas.

If a press is to print in more than one color, a separate printing plate corresponding to each color is required. The plates are each mounted to a separate plate cylinder of the press, and the positions of the cylinders coordinated so that the color components printed by the different cylinders will be in register on the printed copies. Each set of cylinders associated with a particular color on a press is usually referred to as a printing station.

Because of the ready availability of laser equipment and their amenability to digital control, significant effort has been devoted to the development of laser-based imaging systems. Early examples utilized lasers to etch away material from a plate blank to form an intaglio or letterpress pattern. See, e.g., U.S. Pat. Nos. 3,506,779 and 4,347,785. This approach was later extended to production of lithographic plates, for example, by removal of a hydrophilic surface to reveal an oleophilic underlayer. See, e.g., U.S. Pat. No. 4,054,094. These early systems generally required high-power lasers, which are expensive and slow.

A second approach to laser imaging involves the use of thermal-transfer materials. See, e.g., U.S. Pat. Nos. 3,945,318; 3,962,513; 3,964,389; 4,395,946, 5,156,938; 5,171,650; and 5,819,661. With these systems, a polymer sheet transparent to the radiation emitted by the laser is coated with a transferable material. During operation the transfer side of this construction is brought into contact with a receiver sheet, and the transfer material is selectively irradiated through the transparent layer. Irradiation causes the transfer material to adhere preferentially to the receiver. The transfer and receiver materials exhibit different affinities for fountain solution and/or ink, so that removal of the transparent layer together with unirradiated transfer material leaves a suitably imaged, finished printing plate. Typically, the transfer material is oleophilic and the receiver is hydrophilic.

The term “hydrophilic” is herein used in the printing sense to connote a surface affinity for a fluid which prevents ink from adhering thereto. Such fluids include water, aqueous and non-aqueous dampening liquids, and the non-ink phase of single-fluid ink systems. Thus, a hydrophilic surface in accordance herewith exhibits preferential affinity for any of these materials relative to oil-based materials. The term “liquid to which ink will not adhere” connotes not only the traditional dampening solutions as described above, but also extends to polar fluids that may be incorporated within an ink composition itself. For example, so-called “waterborne” inks (or other single-fluid ink systems) contain an aqueous or polar fraction.

Although transfer-type systems are in widespread use, they are not without their deficiencies. A significant and persistent problem stems from dust and dirt that may become trapped between the donor and receiver sheets. Such debris can readily lead to image defects by preventing or interfering with proper transfer of material to the receiver sheet.

Indeed, even in the absence of particulate contaminants, achieving proper adhesion of the transfer material to the receiver can be problematic. In many commercial systems, the transferred material is subjected to some type of post-image treatment (e.g., irradiation to cross-link the transferred material to increase its durability and adhesion, or remelting of the transferred material to cause it to flow into a textured receiver, thereby increasing mechanical bonding upon resolidification). These additional operations involve time, cost, and dedicated equipment.

Another disadvantage of transfer imaging is the cost of specialized receptor sheets, such as grained and anodized aluminum.

### DESCRIPTION OF THE INVENTION

### BRIEF SUMMARY OF THE INVENTION

In accordance with the present invention, the donor rather than the receiver is used as a printing member. The transfer material and the donor substrate on which it is applied differ in terms of surface lithographic affinity, and as a result, following imagewise transfer of material, the donor member may be used as a lithographic printing plate while the receiver serves a filter for image debris and gas.

Accordingly, a method of imaging a recording construction in accordance with the invention begins with a donor member having substrate a transferable material thereover; the substrate and the transferable material differ in affinity for ink and/or a liquid to which ink will not adhere. The donor member is exposed to energy (e.g., imaging radiation, in which case the substrate is transparent thereto) in an imagewise pattern so as to cause release of the transfer material from the donor member in accordance with that pattern. Following the imagewise release, the donor member can be used as a lithographic printing member.

Because the transfer material is applied to the donor substrate in an optimized conventional fashion, adhesion of image to non-image portions is assured; it does not depend on the results of the imaging process itself. Moreover, there may be no need for post-image processing. The receiver member acts only as a trap, capturing debris and gas from imaging the donor member. This helps to protect the operator, device optics and electronic circuitry, as well as the environment.

In addition, the receiver member can also serve as a positive or negative monochrome proof of the image (e.g., if it differs in color from the transfer material). It should be noted, in this regard, that one can match the color of the proof to that of the ink that will eventually be applied to the image through appropriate choice of substrate (e.g., colored paper corresponding to the ink color for positive-working plates) or colorant for the transferable material (e.g., a dye similar to the ink color for negative-working plates).

The mechanism of material transfer can take different forms, so long as the end result is complete removal of the transfer material where it is imaged. In one approach, the transfer material includes a photoconversion material (i.e., a “sensitizer”) that absorbs imaging radiation, causing the the transfer material to be heated where exposed. Transfer can occur by laser ablation transfer (LAT), i.e., explosive disruption of the transfer material resulting in its departure from the substrate; or by a less violent thermal-transfer mechanism, e.g., melt transfer, which relies on a relative affinity of the receiver member for transfer material in a liquid state.

In another approach, the transfer material comprises two or more layers: an oleophilic or hydrophilic outermost layer and, sandwiched between the outermost layer and the substrate, one or more ejection or propellant layers that absorb imaging radiation and, in response, volatilize into gases that cause displacement of the outermost layer.

The printing members of the present invention can be either “positive-working” or “negative-working.” In positive-working versions, an oleophilic transfer material is removed, revealing an underlying hydrophilic layer that will reject ink during printing; in other words, the “image area” is selectively removed to reveal the “background.” In negative-working versions, a hydrophilic transfer material is removed to reveal an underlying ink-receptive substrate.

It should be stressed that, as used herein, the term “plate” or “member” refers to any type of printing member or surface capable of recording an image defined by regions exhibiting differential affinities for ink and/or fountain solution; suitable configurations include the traditional planar or curved lithographic plates that are mounted on the plate cylinder of a printing press, but can also include seamless cylinders (e.g., the roll surface of a plate cylinder), an endless belt, or other arrangement.

### BRIEF DESCRIPTION OF THE DRAWINGS

The foregoing discussion will be understood more readily from the following detailed description of the invention, when taken in conjunction with the accompanying drawings, in which:

FIG. 1 is an enlarged elevation of donor and receiver members in accordance with the invention;

FIG. 2 illustrates the manner in which the donor and receiver members are brought into contact and imaged; and

FIG. 3 shows the results of transfer following imaging and separation of the donor and receiver members.

### DETAILED DESCRIPTION OF THE PREFERRED EMBODIMENTS

Imaging apparatus suitable for use in conjunction with the present printing members includes at least one laser device that emits in the region of maximum plate responsiveness, i.e., whose λₘₐₓ closely approximates the wavelength region where the plate absorbs most strongly. Specifications for lasers that emit in the near-IR region are fully described in U.S. Pat. Nos. Re. 35,512 and 5,385,092 (the disclosures of which are hereby incorporated by reference); lasers emitting in other regions of the electromagnetic spectrum are well-known to those skilled in the art.

Suitable imaging configurations are also set forth in detail in the '512 and '092 patents. Briefly, laser output can be provided directly to the image-recording layer via lenses or other beam-guiding components, or transmitted to the surface of a blank printing plate from a remotely sited laser using a fiber-optic cable. A controller and associated positioning hardware maintain the beam output at a precise orientation with respect to the plate, scan the output thereover, and activate the laser at positions adjacent selected points or areas of the plate. The controller responds to incoming image signals corresponding to the original document or picture being copied onto the plate to produce a precise negative or positive image of that original. The image signals are stored as a bitmap data file on a computer. Such files may be generated by a raster image processor (“RIP”) or other suitable means. For example, a RIP can accept input data in page-description language, which defines all of the features required to be transferred onto the printing plate, or as a combination of page-description language and one or more image data files. The bitmaps are constructed to define the hue of the color as well as screen frequencies and angles.

The imaging apparatus can operate on its own, functioning solely as a platemaker, or can be incorporated directly into a lithographic printing press. In the latter case, however, the imaged printing member must be removed from the plate cylinder and remounted, since imaging has taken place through the back side of the printing member. A stand-alone imaging apparatus can be configured as a flatbed recorder or as a drum recorder, with the lithographic plate blank mounted to the interior or exterior cylindrical surface of the drum.

In the drum configuration, the requisite relative motion between the laser beam and the plate is achieved by rotating the drum (and the plate mounted thereon) about its axis and moving the beam parallel to the rotation axis, thereby scanning the plate circumferentially so the image “grows” in the axial direction. Alternatively, the beam can move parallel to the drum axis and, after each pass across the plate, increment angularly so that the image on the plate “grows” circumferentially. In both cases, after a complete scan by the beam, an image corresponding (positively or negatively) to the original document or picture will have been applied to the surface of the plate.

In the flatbed configuration, the beam is drawn across either axis of the plate, and is indexed along the other axis after each pass. Of course, the requisite relative motion between the beam and the plate may be produced by movement of the plate rather than (or in addition to) movement of the beam.

Regardless of the manner in which the beam is scanned, it is generally preferable (for on-press applications) to employ a plurality of lasers and guide their outputs to a single writing array. The writing array is then indexed, after completion of each pass across or along the plate, a distance determined by the number of beams emanating from the array, and by the desired resolution (i.e., the number of image points per unit length). Off-press applications, which can be designed to accommodate very rapid scanning (e.g., through use of high-speed motors, mirrors, etc.) and thereby utilize high laser pulse rates, can frequently utilize a single laser as an imaging source.

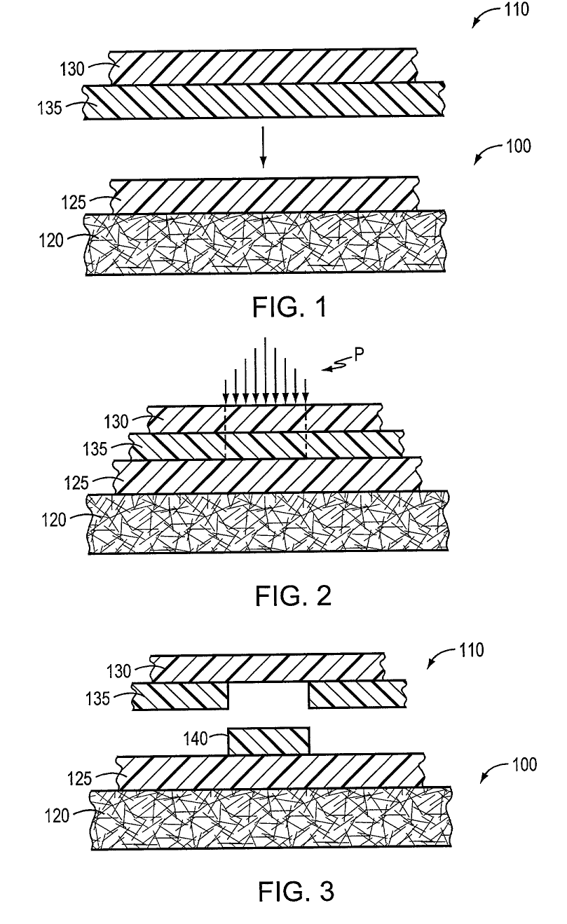

Refer first to FIG. 1, which illustrates a receiver member 100 and a representative donor member 110 in accordance with the invention. Receiver member 100 may include a substrate 120 and, if desired, an overlying polymeric layer 125. As described in greater detail below, the function of the receiver is solely to ensure full displacement of transfer material from donor member 110; it does not participate in the printing process. Accordingly, the characteristics of receiver member 100 are dictated largely by affinity for transfer material and economics (since receiver member 100 is typically discarded following use).

For example, a porous material such as paper is often a suitable material for substrate 120. In order to maintain intimate contact between receiver member 100 and donor member 110, a porous substrate 120 may be subjected to a vacuum against its free side (i.e., the side opposite the surface that will be in contact with donor member 110). The vacuum not only helps to establish and maintain this contact, but can also assist with the transfer operation itself, drawing the mobilized transfer material toward receiver member 100 during imaging. Platemakers, for example, may utilize vacuum cylinders having porous bodies that allow a vacuum to be applied to plates mounted thereon.

If desired, receiver member 100 may be fabricated or selected to contrast in tonality and/or color with transfer material 135, so that following imaging, receiver member 100 will provide a visible record of the imaged pattern that can serve as a proof. The transfer material 135 may be colored to provide contrast within the finished plate itself (i.e., with respect to substrate 130, discussed below). Coloration may be conferred, for example, by the sensitizer.

It is possible to impregnate papers with materials, such as activated carbon, that are effective at capturing gases and ultrafine debris generated during the imaging process, thereby reducing unwanted environmental contamination. Calgon Carbon Corporation, Pittsburgh, Pa. produces several chemically impregnated activated carbon products suitable for use as substrate 120. The activated carbon surface participates in chemical reactions to remove or reduce contaminants that are not effectively removed by physical adsorption alone (e.g., acidic gases from nitrocellulose decomposition, H₂S, amines, metals, etc.).

Also useful are environmental products such as vacuum-cleaner bag materials produced by Genvac, Missouri City, Tex. Unlike ordinary paper or lined paper, the 3M FILTRETE vacuum filters include a special blend of FILTRETE fibers as filtering material in the paper. FILTRETE media is made of 100% polypropylene fibers that are electrostatically charged to capture small particles.

Donor member 110 includes a film layer or substrate 130 that is transparent to imaging radiation and, bonded thereto, a transfer layer 135 that responds to imaging radiation as described below. In a positive-working version, transfer material 135 is oleophilic and film layer 130 is hydrophilic. So long as as it will transfer to receiver member 100 and exhibit sufficient printing durability where unexposed, virtually any oleophilic material that is released in response to imaging radiation may be used as transfer material 135. For example, transfer material 135 may be a urethane, epoxy or phenol-aldehyde (Novolak) polymer composition into which a radiation sensitizer—such as carbon black or an IR-absorptive dye—has been dispersed or dissolved. Self-oxidizing materials, such as nitrocellulose, are also useful. A suitable composition, described in U.S. Pat. No. 5,339,737, utilizes a combination of nitrocellulose and hexamethoxymethylmelamine in a 2-butanone solvent; the mixture is combined with a sensitizer applied as a coating.

Other suitable materials include conventional LAT transfer layers, as described in U.S. Pat. Nos. 3,945,318; 3,962,513; 3,964,389; 4,245,003; 4,395,946; 4,588,674; and 4,711,834, the disclosures of which are hereby incorporated by reference. U.S. Pat. No. 5,819,661, the disclosure of which is also incorporated by reference, describes a thermal-transfer approach that does not involve ablation. In response to an imaging pulse, a transfer material reduces in viscosity to a flowable state. The material exhibits a higher melt adhesion for a receiver substrate than for the carrier sheet to which it is initially bound, so that in a flowable state it transfers completely to the receiver substrate. Following transfer, the donor sheet, along with untransferred material, is removed from the receiver substrate. Transfer materials in accordance with the '661 patent may be self-oxidizing (e.g., based on nitrocellulose) but formulated to interact in a controlled fashion with imaging radiation. An imaging pulse heats the transfer material to a flowable state (e.g., by melting layer 135 or raising its temperature above the glass-transition point T_{g}), and in that state, layer 135 preferentially adheres to receiver member 100. To achieve controlled, non-ablative heating, layer 135 may be formulated with a limited-stability radiation absorber or with conventional absorbers at concentrations too low to support ablation; non-ablative heating may also be achieved through control of the imaging device, e.g., in terms of power density and/or dwell time.

It should be emphasized that film layer 130 need not be a single layer or even a single material. Instead, multi-layer composites consisting of different layers with particular advantageous properties may be employed. Typically, this layer will be polyester, used in its native oleophilic state or treated to exhibit hydrophilicity.

In another approach, illustrated in FIG. 4, layer 135 is an oleophilic or oleophilized ceramic. For purposes hereof, the term “ceramic” is intended to connote refractory oxides, carbides, and nitrides of metals (e.g., a transition metal such as titanium) or nonmetals. These have both high melting points (generally 1900° C. or higher) and high Young's moduli (typically 200 kN/mm² or higher). Moreover, in ceramic materials the high values of Young's modulus are preserved up to high temperatures approaching the melting point. Suitable materials are durable at low application thicknesses and may also include a surface treatment and/or dopants, such as copper, gold, silver, platinum, or palladium to improve ink receptivity. Generally, a ceramic will be deposited to a thickness of at least 200 Å.

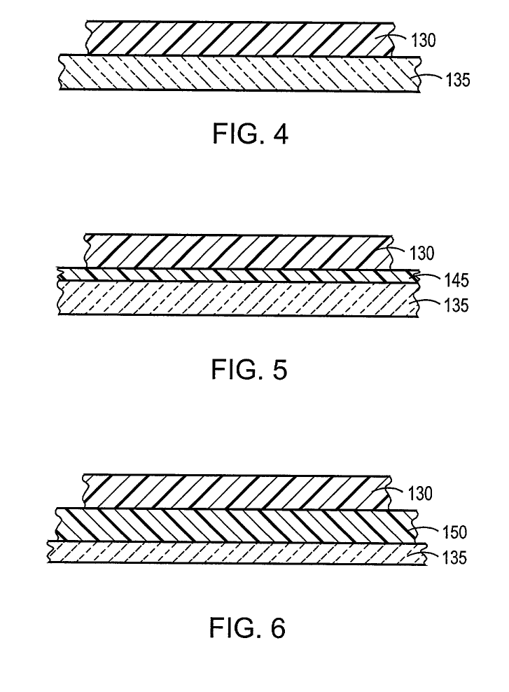

Refer now to FIGS. 2 and 3, which illustrate the manner in which a suitable construction is imaged in accordance with the present invention. As shown in FIG. 2, donor member 110 is brought into intimate contact with receiver member 100; if substrate 120 is porous, a vacuum is preferably applied to the free side thereof in order to enhance contact and filtration. An imaging pulse P from a laser or other suitable source strikes the construction, illuminating an area indicated by the dashed boundaries.

Layer 135 is formulated to interact in a controlled fashion with imaging radiation, transferring material to layer 120 or, if utilized, layer 125 in the region of exposure. Thus, the construction is irradiated in an imagewise manner, causing transfer of material to receiver member 100 in accordance with that pattern. When the donor member 110 is removed from receiver member 100, the transferred material 140 remains on receiver member 100. The difference in lithographic affinities between layers 130 and 135 results in a finished printing plate plate.

If applied, layer 125 is typically a light coating of a thermoplastic material. When subjected to heat from the transfer material 135 as the latter undergoes exposure, layer 125 will become tacky in the exposure region, enhancing adhesion to layer 135 of the donor member. Unaffected regions of layer 125 will not exhibit any substantial adhesion to layer 135; as a result, when the donor and receiver members are separated, layer 125 will not damage the mechanical integrity of layer 135.

Suitable thermoplastic materials include phenol-aldehyde polymers (see, e.g., U.S. Pat. No. 4,966,798, which describes Novolaks with softening temperatures in the 100-150° C. range) and hot-melt adhesives (e.g., a mixture of ethylene/vinyl acetate copolymer and a tackifier such as a modified rosin ester, as described, for example, in U.S. Pat. No. 5,593,808).

Alternatively, instead of laser activation, transfer of the thermal material can be accomplished through direct contact. U.S. Pat. No. 4,846,065, for example, describes the use of a digitally controlled pressing head to transfer oleophilic material to an image carrier.

Layer 130 is generally polymeric in nature to afford the necessary transparency to imaging radiation, and should exhibit sufficient dimensional stability to act as a printing-member substrate. Preferably layer 130 is substantially transparent to imaging radiation, meaning, for purposes hereof, that it transmits at least 95% of incident imaging radiation. Also, layer 130 should not exhibit excessive scattering of imaging radiation, since scattering can both reduce the effective image resolution and increase power requirements. For example, polyester films having thicknesses ranging from 0.005 to 0.012 inch may be used advantageously. Other suitable materials may include polyethylene naphthalate; polyamides; polycarbonates; polymeric cellulose esters such as cellulose acetate; fluorine polymers such as poly(vinylidene fluoride) or poly(tetrafluoroethylene-cohexafluoropropylene); polyethers such as polyoxymethylene; polyacetals; polyolefins such as polystyrene, polyethylene, polypropylene or methylpentene polymers; and polyimides such as polyimide-amides and polyether-imides.

In one embodiment, layer 130 is a lithographically durable, hydrophilic polymer material. Suitable materials include, for example, homopolymers and copolymers of vinyl alcohol (e.g., polyvinyl alcohol), acrylamide, methylol acrylamide, methylol methacrylamide, acrylic acid, methacrylic acid, hydroxyethyl acrylate, hydroxyethyl methacrylate, maleic anhydride/vinylmethylether copolymers, hydroxyethyl cellulose, and polyvinyl pyrrolidone. As explained above, to serve as layer 130 the material should be dimensionally stable and substantially transparent to imaging radiation. It should be noted, however, that these same classes of material, whether or not transparent, can be combined with a sensitizer and used as a hydrophilic layer 135.

In an alternative approach, illustrated in FIG. 5, layer 130 is polyester (e.g., the MYLAR film product sold by E.I. du Pont de Nemours Co., Wilmington, Del.) that has been treated to confer surface hydrophilicity. For example, layer 130 may be coated with a thin (e.g., as thin as 5 nm, or thicker as desired) layer 145 of a polymer, such as a tightly crosslinked acrylate polymer, having carboxylic acid, sulfonic acid, sulfonamido, and/or hydroxyl groups. A suitable combination of layers 130, 145 is illustrated by the MYRIAD 2 material supplied by Xanté Corp. noted in U.S. Pat. No. 6,162,578, Examples 5-8. This material is a hydrophilic ceramic coated on a 0.1 mm polyester base. It should be noted, however, that layer 135 may be polymeric rather than a ceramic material or a combination thereof.

In one exemplary formulation, a mixture of 5% colloidal silica with 1% 3-aminopropyltriethoxysilane, 2% carbon (CABOJET 200 from the Cabot Company, Billerica, Mass.) and 0.1% ZONYL FSN surfactant (du Pont, Wilmington, Del.) is coated at 14 cm³/m² onto a polyethylene teraphthalate layer 130. During the drying process, the coating is held at 118° C. for 3 minutes. The result is a single layer with a hydrophilic surface to which layer 135 is applied. In another exemplary formulation, a mixture of 10 g of carbon (Cabot Black Pearls 700) in 400 g methyl ethyl ketone and 400 g methylisobutyl ketone with 21 g of nitrocellulose is tumbled with 1-mm-diameter zirconium oxide beads for 24 hours. The beads are filtered off and the suspension coated onto polyethylene teraphthalate at 3.0 cm³/ft² wet laydown. When dry, the polyester is overcoated with a solution of 120 g of colloidal silica stabilized with ammonia mixed with 280 g of water, 2 g of aminopropyltriethoxysilane and 0.1 g of ZONYL FSN surfactant; the coating may be applied at 16 cm³/m² wet laydown and dried for 3 minutes at 118° C. (It should be noted that this layer can, under high-energy imaging conditions, itself be ablated—i.e., serve as a transfer layer in place of layer 135.) Other useful formulations are disclosed in U.S. Pat. No. 6,153,352 at col. 4, line 57 to col. 13, line 14 and U.S. Pat. No. 5,985,515; the entire disclosures of these references are hereby incorporated by reference.

In another approach, layer 145 may be an adhesion-promoting layer, e.g., a hydrophilic binder combined with colloidal silica as disclosed in published European application nos. EP-A 619524, EP-A 620502 and EP-A 619525. Preferably, the amount of silica in the adhesion-promoting layer is between 200 mg/m² and 750 mg/m². Further, the ratio of silica to hydrophilic binder is preferably more than 1 and the surface area of the colloidal silica is preferably at least 300 m²/g, and more preferably at least 500 m²/g.

Plasma polymerization with hydrocarbons or hydrocarbon compounds and oxygen can also be used to alter affinity characteristics. For example, subjecting a substrate (e.g., polyester) to a plasma comprising oxygen and a hydrocarbon compound can produce stable hydrophilic surfaces as disclosed in U.S. Pat. Nos. 4,632,844; 5,874,127; 4,312,575; and 5,925,494, the entire disclosures of which are hereby incorporated by reference. It should be noted, conversely, that plasma polymerization of a hydrocarbon can be used to produce a stable oleophilic surface as disclosed in U.S. Pat. Nos. 6,090,456; 4,412,903; 4,490,229; and 4,060,660, the entire disclosures of which are also hereby incorporated by reference.

In still another approach, layer 130 may be bombarded with a material that alters surface properties. For example, as described in U.S. Pat. No. 5,829,353 (the entire disclosure of which is hereby incorporated by reference), the affinity characteristics of a material may be strongly affected—and thereby selectively modulated—through implantation of one or more inorganic materials, typically in the form of ions and/or atoms (or molecules). The desired characteristics are achieved by chemical surface modification of the material rather than by texturing or deposition of a new surface layer. an inorganic material (typically in molecular, atomic or ionic form) is driven into the surface of layer 130. In preferred approaches, metal ions and/or atoms are impregnated into a polymer matrix by sputtering or by ion implantation so as to form an in situ dispersion. Either process may, if desired, be combined with reactive etching to improve the penetration of ions. Metals such as titanium, aluminum, magnesium, and zinc reactively sputtered with oxygen to produce oxides are useful in enhancing hydrophilicity (while, as noted above, metals such as copper, gold, silver, platinum, and palladium can all be used to enhance oleophilicity). In addition to metals and metal alloys, other inorganic materials—such as intermetallics and metal-nonmetal compounds—can also be used. For example, hydrophilicity can be enhanced through impregnation with titanium oxide.

Still a further alternative is to utilize, for layer 130, materials that undergo surface conversion from a hydrophobic condition to a hydrophilic condition upon exposure to actinic (e.g., UV) radiation. For example, as described in U.S. Pat. Nos. 6,048,654 and 6,106,984, the entire disclosures of which are hereby incorporated by reference, a thin layer 145 comprising TiO₂, ZnO or any of various other compounds can be rendered hydrophilic through irradiation. See also Watanabe, Ceramics 31:837 (1966). This approach can be employed to advantage in the present invention by providing an initially oleophilic layer 130 that bonds readily with an oleophilic layer 135, resulting in good interlayer adhesion. Following imagewise removal of layer 135, layer 130 is exposed to actinic radiation, rendering the exposed portions hydrophilic.

In a negative-working version of the donor member 110, transfer material 135 is hydrophilic and film layer 130 is oleophilic. Layer 130 may, for example, be a polyester film (e.g., the MYLAR product noted above). Once again, layer 135 may be polymeric (as in the examples given above) or inorganic in nature. For example, layer 135 may comprise a metallic inorganic compound of at least one metal with at least one non-metal, or a mixture of such compounds. It is generally applied at a thickness of 100-5000 Å or greater; however, optimal thickness is determined primarily by durability concerns and imaging-radiation absorption characteristics, and secondarily by economic considerations and convenience of application. The metal component of layer 135 may be a d-block (transition) metal, an f-block (lanthanide) metal, aluminum, indium or tin, or a mixture of any of the foregoing (an alloy or, in cases in which a more definite composition exists, an intermetallic). Preferred metals include titanium, zirconium, vanadium, niobium, tantalum, molybdenum and tungsten. The non-metal component of layer 135 may be one or more of the p-block elements boron, carbon, nitrogen, oxygen and silicon. A metal/non-metal compound in accordance herewith may or may not have a definite stoichiometry, and may in some cases (e.g., Al—Si compounds) be an alloy. Preferred metal/non-metal combinations include TiN, TiON, TiOₓ (where 0.9≦x≦2.0), TiAlN, TiAlCN, TiC and TiCN.

In this case, it may be preferable to utilize a hardcoat polymer for layer 130 or layer 145 in order to enhance compatibility with the very hard inorganic layer. For example, as described in U.S. Pat. No. 5,783,364, a layer 145 harder than layer 130 can be a highly crosslinked polyacrylate, which may be applied under vacuum conditions, or a polyurethane. A representative thickness range for such a layer 145 is 1-2 μm. Another suitable material is poly(acrylonitrile-covinylidene chloride-co-acrylic acid) with a weight ratio of 14:79:7, applied at 0.07 g/m².

It should also be noted that a protective layer may be deposited over layer 135. If added, this layer can serve a variety of beneficial functions: providing protection against handling and environmental damage, and also extending plate shelf life, but mostly disappearing during make-ready; assisting with cleaning by entraining debris and carrying it away as the layer itself is removed during press make-ready; and accelerating plate “roll-up”—that is, the number of preliminary impressions necessary to achieve proper quality of the printed image.

A hydrophilic protective layer may comprise a polyalkyl ether compound with a molecular weight that depends on the mode of application and the conditions of plate fabrication. For example, when applied as a liquid, the polyalkyl ether compound may have a relatively substantial average molecular weight (i.e., at least 600) if the plate undergoes heating during fabrication or experiences heat during storage or shipping; otherwise, lower molecular weights are acceptable. A coating liquid should also exhibit sufficient viscosity to facilitate even coating at application weights appropriate to the material to be coated.

Another representative formulation for a hydrophilic protective coating comprises 2.5 parts polyvinyl alcohol (e.g., the Airvol 203 product sold by Air Products and Chemicals, Allentown, Pa.) dispersed in 89.37 parts deionized water at room temperature using sufficient agitation to wet out all particles with water. The temperature of the dispersion is elevated to 85-96° C., and held for 30 min with continuous agitation. After the temperature of the resulting clear solution cools to room temperature, 0.13 parts diethyleneglycol and 8 parts methyl alcohol are added.

The solution is coated over a ceramic printing plate surface and dried to provide a protective layer at a thickness of about 0.2 to 0.4 μm.

More generally, the protective layer is preferably applied at a minimal thickness consistent with its roles as discussed above. The thinner the layer can be made, the more quickly it will be removed during press make-ready, the shorter will be the roll-up time, and the less the layer will affect the imaging sensitivity of the plate.

In still another alternative, illustrated in FIG. 6, transfer of layer 135 may be promoted by a propellant layer 150, which exhibits a high degree of absorbance for imaging laser radiation, and ablates—that is, virtually explodes into a cloud of gas and debris—in response to a laser pulse. This action, which may be further enhanced by self-oxidizing binders (as in the case, for example, of nitrocellulose materials), ensures complete removal of the transfer material from its carrier. U.S. Pat. Nos. 5,156,938 and 5,171,650 (the disclosures of which are hereby incorporated by reference), for example, describe “dynamic release layers” that absorb imaging radiation at a rate sufficient to effect ablation mass transfer.

The terms and expressions employed herein are used as terms of description and not of limitation, and there is no intention, in the use of such terms and expressions, of excluding any equivalents of the features shown and described or portions thereof, but it is recognized that various modifications are possible within the scope of the invention claimed.

What is claimed is:

1. A method of imaging a recording construction, the method comprising the steps of:
a. providing a donor member comprising a substrate and a transferable material thereover, the substrate and the transferable material differing in affinity for at least one of ink and a liquid to which ink will not adhere;
b. imagewise exposing the donor member to energy through the substrate so as to cause imagewise release of the transfer material from the donor member onto a receiver member; and
c. printing with the donor member following the imagewise release and separation of the donor member from the receiver member.

2. The method of claim 1 wherein the energy is thermal energy.

3. The method of claim 1 wherein the energy is imaging radiation and the substrate is substantially transparent thereto.

4. The method of claim 1 wherein the transfer material is oleophilic and the substrate is hydrophilic, the irradiated material corresponding to a background portion of an image.

5. The method of claim 1 wherein the transfer material is hydrophilic and the substrate is oleophilic, the irradiated material corresponding to an image.

6. The method of claim 1 wherein the receiver member is disposed adjacent to the donor member, the receiver member receiving the released transfer material, and further comprising the step of dissociating the receiver member from the transfer member to remove the released material prior to the printing step.

7. The method of claim 6 wherein the receiver is porous.

8. The method of claim 7 further comprising the step of subjecting the receiver member to a vacuum during imaging, the vacuum assisting in withdrawal from the donor member of transfer material exposed to imaging radiation.

9. The method of claim 5 wherein the receiver comprises a thermoplastic material, the thermoplastic material becoming tacky adjacent to portions of the donor member exposed to imaging radiation so as to develop adhesion to the transfer material at said exposed portions.

10. The method of claim 4 wherein the substrate is a polyvinyl alcohol chemical species.

11. The method of claim 4 wherein the substrate is a polymer film having a hydrophilic surface coating.

12. The method of claim 11 wherein the surface coating is an acrylate polymer incorporating hydrophilic functional groups.

13. The method of claim 11 wherein the surface coating comprises silica.

14. The method of claim 11 wherein the surface coating comprises an oxidized hydrocarbon applied by plasma polymerization.

15. The method of claim 11 wherein the surface coating is formed by bombarding the polymer film with a hydrophilic material to achieve integration of the hydrophilic material within the polymer film.

16. The method of claim 15 wherein the hydrophilic material is an oxide of at least one of aluminum, magnesium, zinc.

17. The method of claim 11 wherein the surface coating is transformable from an oleophilic state to a hydrophilic state through exposure to actinic radiation.

18. The method of claim 4 wherein the transfer material is a polymeric material comprising a radiation-absorbing material thermally responsive to imaging radiation so as to cause the release.

19. The method of claim 4 wherein the transfer material comprises (a) an oleophilic polymer layer and (b) between the oleophilic polymer layer and the substrate, at least one layer comprising a radiation-absorbing material thermally responsive to imaging radiation so as to cause the release.

20. The method of claim 4 wherein the transfer material is an oleophilic ceramic.

21. The method of claim 20 wherein the oleophilic ceramic member comprises at least one of carbon, boron, silicon, and nitrogen.

22. The method of claim 5 wherein wherein the transfer material is a polymeric material comprising a radiation-absorbing material thermally responsive to imaging radiation so as to cause the release.

23. The method of claim 5 wherein the transfer material comprises (a) a hydrophilic polymer layer and (b) between the hydrophilic polymer layer and the substrate, at least one layer comprising a radiation-absorbing material thermally responsive to imaging radiation so as to cause the release.

24. The method of claim 5 wherein the transfer material is a surface-modified metallic inorganic material.

25. The method of claim 1 wherein the receiver member is formulated to chemically trap imaging debris and gas.

26. The method of claim 1 wherein the receiver member is formulated to electrostatically trap imaging debris.
